(19) United States
(12) Patent Application Publication
(10) Pub. No.: US 2023/0416913 A1
(43) Pub. Date: Dec. 28, 2023

(54) MODULES FOR DELIVERY SYSTEMS AND RELATED METHODS

(71) Applicant: ENTEGRIS, INC., Billerica, MA (US)

(72) Inventors: Bryan C. Hendrix, Danbury, CT (US); Carlo Waldfried, Middleton, MA (US); Scott L. Battle, Cedar Park, TX (US); Gavin Richards, Newtown, CT (US); Benjamin R. Garrett, Leander, TX (US)

(21) Appl. No.: 18/215,757

(22) Filed: Jun. 28, 2023

Related U.S. Application Data
(60) Provisional application No. 63/356,256, filed on Jun. 28, 2022.

(51) Int. Cl. C23C 16/455; C23C 16/44

(52) U.S. Cl. CPC C23C 16/45544; C23C 16/4404; C23C 16/45561; C23C 16/52

(57) ABSTRACT

A system including a chemical supply cabinet (e.g., such as a chemical supply cabinet configured to contain an ampoule), a module configured to modify a surface, and a control unit connected to the module, wherein the control unit is configured to direct the modifying of the surface.

### RELATED DOCUMENTS

This disclosure claims priority from U.S. provisional patent application No. 63/356,256 with a filing date of Jun. 28, 2022, which document is incorporated by reference herein.

### FIELD

This disclosure relates generally to delivery systems.

### BACKGROUND

A delivery system designed for transport of solid precursor materials can be used in manufacturing processes. Such systems can include ampoules configured to contain solid precursor materials.

### SUMMARY

A delivery system designed for transport of vapor from a solid or liquid precursor materials can be used in manufacturing processes. Delivery systems can be placed in enclosures or cabinets to isolate different potential hazards from each other and from the occupied manufacturing area. Some examples include separating potential leaks of toxic or flammable vapors from sources of ignition or human interaction. The delivery systems can also be located in a different part of the factory, such as the subfabrication area of a semiconductor manufacturing plant. Such delivery systems can include ampoules configured to contain solid precursor materials.

In addition to vapors being potentially toxic or flammable, vapors can also be corrosive. In the case of vapors that are corrosive or reactive with the tubing or “wetted” surfaces from the cabinet to the point of use, surface treatments and coatings can be used to inhibit or eliminate the corrosion or reactions. Currently available surface treatments and coatings require time-intensive and sometimes hazardous procedures to effectively coat or treat all of the wetted surfaces from and including the delivery system, the tubing from one area of the factory to another, and all of the desired surfaces at the point of vapor use. In addition, installation and removal of the surface treatment systems can introduce contamination and sometimes leaves small areas of the wetted surface un-treated.

Vapors delivered from the chemical supply cabinets can be corrosive. In some examples, when tool or line maintenance is performed, lines are exposed to fabricated air. Although lines are thoroughly pump-purged at elevated temperatures, there are still reaction byproducts (e.g., FeCl₃ or CrC1₃) that remain on the surfaces. The reaction byproducts can drive corrosion during exposure to fabricated air or upon subsequent high temperature cycles.

Some embodiments of a delivery system include a chemical supply cabinet (e.g., a chemical supply cabinet configured to contain an ampoule, such as ampoule containing vapor source material) and a module configured to modify a surface. In some embodiments, a control unit can be connected to the module, and the control unit is configured to direct the modifying of the surface.

In some examples, coatings can be applied to parts before installation, thereby significantly reducing corrosion. However, some lines are extremely long and welded in-place from the subfabrication process or installation. Other parts of delivery system, e.g., the lines and manifolds, can have connections that are not coated.

One solution is to coat the parts of the manufacturing system after the manufacturing system is completely installed. The wetted components can be heated including the lines and/or valves from the chemical supply cabinet to the tool, the lines and/or valves in the cabinet, and/or the lines and/or valves in the tool. Coating can be done on the original installation of the manufacturing system. Re-coating can be performed after certain maintenance events, after predetermined amount of time, and/or after certain events (e.g., a detection of corrosion of a surface of the manufacturing system including the delivery system or the tool). Other surface treatment options can also be incorporated into the cabinet such as surface deposition of vapors, such as fluorine (F₂) or nitrogen (N₂).

At least some of these embodiments of the delivery system are used in atomic layer deposition (ALD), chemical vapor deposition (CVD), or both processes. Solid precursor materials can be used in fabrication of microelectronic devices. In some embodiments, the solid precursor materials are a variety of organic precursors, inorganic precursors, metal organic precursors, or combination(s) thereof.

In some aspects, the techniques described herein relate to a system including: a chemical supply cabinet; a module configured to modify a surface; and a control unit connected to the module, wherein the control unit is configured to direct the modifying of the surface.

In some aspects, the techniques described herein relate to a system, wherein the system is configured to connect to a semiconductor processing tool.

In some aspects, the techniques described herein relate to a system, wherein the surface includes an interior surface of the semiconductor processing tool.

In some aspects, the techniques described herein relate to a system, wherein the module is configured to modify the surface by altering a composition of the surface.

In some aspects, the techniques described herein relate to a system, wherein the module is configured to modify the surface by forming a coating on the surface.

In some aspects, the techniques described herein relate to a system, wherein the module is an atomic layer deposition coating module.

In some aspects, the techniques described herein relate to a system, wherein the module is configured to be connected to the chemical supply cabinet from an exterior of the chemical supply cabinet.

In some aspects, the techniques described herein relate to a system, wherein the control unit is configured to automatically direct the module to modify the surface of the system.

In some aspects, the techniques described herein relate to a method including: connecting a module to a chemical supply cabinet; after connecting the module to the chemical supply cabinet, controlling the module to modify a surface; and modifying the surface via the module.

In some aspects, the techniques described herein relate to a method, wherein the module is an atomic layer deposition coating module.

In some aspects, the techniques described herein relate to a method, wherein the modifying the surface includes forming a coating on the surface.

In some aspects, the techniques described herein relate to a method, wherein the forming the coating on the surface includes using atomic layer deposition.

In some aspects, the techniques described herein relate to a method, further including connecting an ampoule to the chemical supply cabinet, connecting a supply line to the chemical supply cabinet, connecting a tool to the supply line, or combinations thereof.

In some aspects, the techniques described herein relate to a method, wherein the connecting the module to the chemical supply cabinet includes connecting the module to the chemical supply cabinet, while the module remains on an exterior of the chemical supply cabinet.

In some aspects, the techniques described herein relate to a method, wherein the controlling the module includes controlling the module via a control unit to automatically modify the surface.

In some aspects, the techniques described herein relate to a system including: a chemical supply cabinet, wherein a structure of the chemical supply cabinet defines an interior volume of the chemical supply cabinet; a module connected to the interior volume of the chemical supply cabinet; a tool connected to the module; and a supply line connecting the chemical supply cabinet to the tool, wherein, after connecting the module to the chemical supply cabinet, the module is configured to modify a surface.

In some aspects, the techniques described herein relate to a system, wherein a control unit is connected to the module, and wherein the control unit is configured to direct the module.

In some aspects, the techniques described herein relate to a system, wherein the module is an atomic layer deposition coating module.

In some aspects, the techniques described herein relate to a system, wherein the tool is a semiconductor processing tool.

In some aspects, the techniques described herein relate to a system, wherein the surface includes an interior surface of the chemical supply cabinet, an interior surface of the supply line, a wettable-surface of the tool, or combinations thereof.

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced. Like numbers represent the same or similar parts throughout.

FIG. 1 shows a manufacturing system according to some of the embodiments.

FIG. 2 shows a chemical supply cabinet according to some of the embodiments.

FIG. 3 shows a chemical supply cabinet according to some of the embodiments.

FIG. 4 shows a module according to some of the embodiments.

FIG. 5 shows a flowchart according to some of the embodiments of the methods for modifying a surface.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “ampoule” means a sealed container that holds chemicals (e.g., a liquid chemical, a solid chemical, or gaseous chemical).

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Generally, this term means a configuration where something is sandwiched by two or more other things. At the same time, the term “between” can describe something that is directly next to two opposing things. Accordingly, in any one or more of the embodiments disclosed herein, a particular structural component being disposed between two other structural elements can be:
disposed directly between both of the two other structural elements such that the particular structural component is in direct contact with both of the two other structural elements;
disposed directly next to only one of the two other structural elements such that the particular structural component is in direct contact with only one of the two other structural elements;
disposed indirectly next to only one of the two other structural elements such that the particular structural component is not in direct contact with only one of the two other structural elements, and there is another element which juxtaposes the particular structural component and the one of the two other structural elements;
disposed indirectly between both of the two other structural elements such that the particular structural component is not in direct contact with both of the two other structural elements, and other features can be disposed therebetween; or
any combination(s) thereof.

As used herein “embedded” means that a first material is distributed throughout a second material.

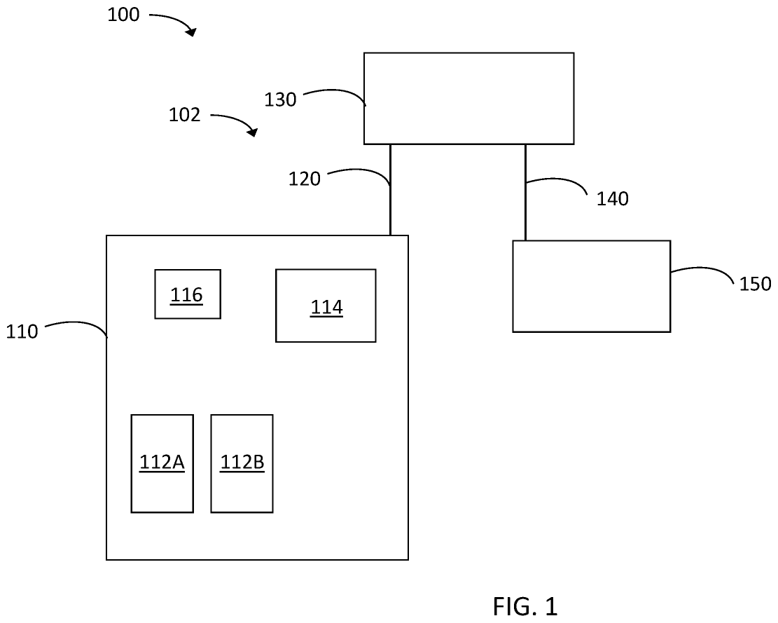

FIG. 1 shows a manufacturing system 100 with a delivery system 102 according to some of the embodiments. The delivery system 102 includes a chemical supply cabinet 110 and a supply line 120. The manufacturing system 100 further includes a tool 130, a vacuum pump line 140, and a vacuum pump 150. The chemical supply cabinet 110 includes a first ampoule 112A, a second ampoule 112B (the first ampoule 112A and the second ampoule 112B are collectively referred to as the ampoules 112), a module 114, and a control unit 116. In some embodiments, the chemical supply cabinet 110 does not include the control unit 116.

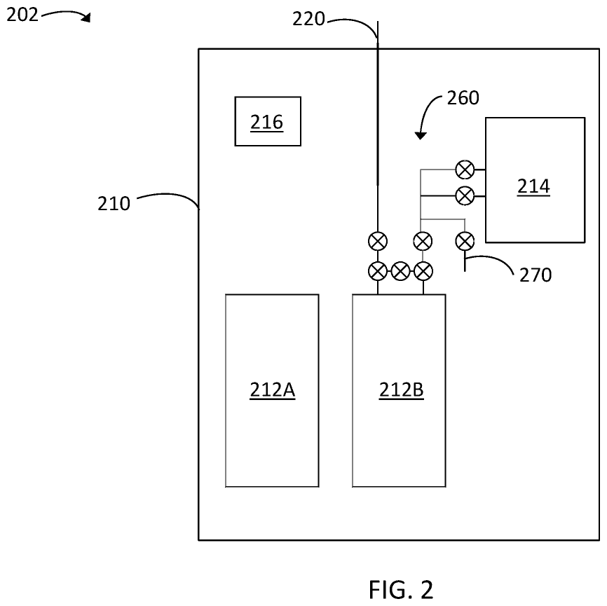

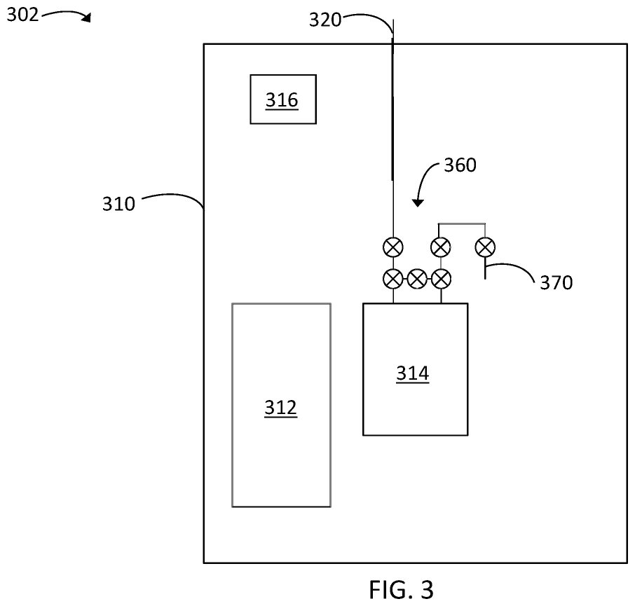

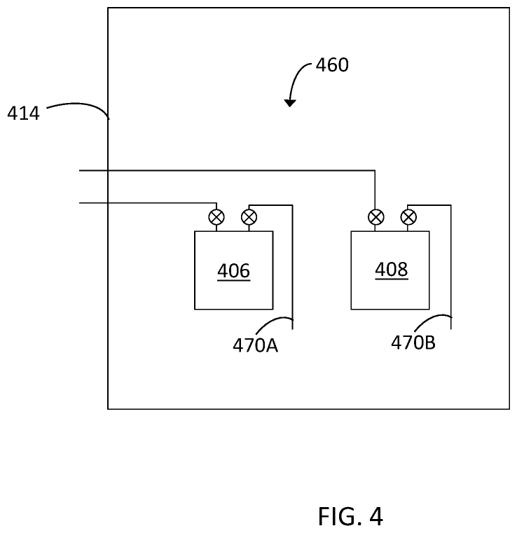

The ampoules 112 are configured to modify a surface by altering a composition (e.g., a chemical composition) of the surface. In some embodiments, the surface is a surface of the manufacturing system 100. For example, the surface can be all wettable-surfaces of the manufacturing system 100. In some embodiments, wettable surfaces of the manufacturing system 100 include an interior surface within the chemical supply cabinet 110 (e.g., processing lines of the chemical supply cabinet 110), an interior surface of the supply line 120, a wettable-surface of the tool 130. In some embodiments, the surface is a surface of the delivery system 102 (i.e., a surface within the chemical supply cabinet 110 and the supply line 120) and the tool 130. The surface of the chemical supply cabinet 110 can refer to lines of the chemical supply cabinet 110. For example, see processing lines 260 of a chemical supply cabinet 210 in FIG. 2, processing lines 360 of supply cabinet 310 of FIG. 3, and processing lines 460 of a module 414 of FIG. 4

In some embodiments, a structure of the chemical supply cabinet 110 defines an interior volume of the chemical supply cabinet 110. In some embodiments, the module 114 is connected to the interior volume of the chemical supply cabinet 110. In some embodiments, the tool 130 can be connected to the module 114 (e.g., via processing lines). In some embodiments, the supply line 120 connects the chemical supply cabinet 110 to the tool 130. In some embodiments, after connecting the module 114 to the chemical supply cabinet 110 (where the module 114 can remain on the exterior of the chemical supply cabinet 110 or be located in an interior of the chemical supply cabinet 110), the module 114 is configured to modify a surface.

In some embodiments, the ampoules 112 are precursor ampoules. In some embodiments, the first ampoule 112A and the second ampoule 112B are the same ampoule. In some embodiments, the first ampoule 112A and the second ampoule 112B are different. For example, the first ampoule 112A and the second ampoule 112B can differ from one another in size, shape, and contents. In some embodiments, the ampoules 112 are metal (e.g., a sealed metal container). The ampoules 112 are not restricted to a particular shape and/or size.

In some embodiments, the precursor comprises a precursor capable of being vaporized by application of thermal energy and irradiation. The vaporizable precursor may be present as a solid, as a liquid, or as a solid and a liquid. For example, in some embodiments, the vaporizable precursor comprises a vaporizable solid precursor. In some embodiments, the vaporizable precursor comprises a vaporizable liquid precursor. In some embodiments, the vaporizable precursor comprises a vaporizable solid precursor and a vaporizable liquid precursor. It will be appreciated that other types of vaporizable precursors may be used herein without departing from the scope of this disclosure.

The vaporizable precursor may comprise, consist of, or consist essentially of at least one of an elemental metal, a metal halide, a metal oxyhalide, an organometallic compound, a metalorganic complex, or any combination thereof.

In some embodiments, the vaporizable precursor comprises, consists of, or consists essentially of at least one of dimethyl hydrazine, trimethyl aluminum (TMA), hafnium chloride (HfCl₄), zirconium chloride (ZrCl₄), indium trichloride, indium monochloride, aluminum trichloride, titanium iodide, tungsten carbonyl, Ba(DPM)₂, bis dipivaloyl methanato strontium (Sr(DPM)₂), TiO(DPM)₂, tetra dipivaloyl methanato zirconium (Zr(DPM)₄), decaborane, octadecaborane, indium, antimony, sodium tetrafluoroborates, precursors incorporating alkyl-amidinate ligands, organometallic precursors, zirconium tertiary butoxide (Zr(t-OBu)₄), tetrakisdiethylaminozirconium (Zr(Net₂)₄), tetrakisdiethylaminohafnium (Hf(Net₂)₄), tetrakis (dimethylamino) titanium (TDMAT), tertbutyliminotris (diethylamino) tantalum (TBTDET), pentakis (dimethylamino) tantalum (PDMAT), pentakis (ethylmethylamino) tantalum (PEMAT), tetrakisdimethylaminozirconium (Zr(NMe₂)₄), hafniumtertiarybutoxide (Hf(tOBu)₄), xenon difluoride (XeF₂), xenon tetrafluoride (XeF₄), xenon hexafluoride (XeF₆), or any combination thereof.

In some embodiments, the vaporizable precursor comprises, consists of, or consists essentially of at least one of decaborane, hafnium tetrachloride, zirconium tetrachloride, indium trichloride, metalorganic β-diketonate complexes, tungsten hexafluoride, cyclopentadienylcycloheptatrienyl-titanium (CpTiCht), aluminum trichloride, titanium iodide, cyclooctatetraenecyclo-pentadienyltitanium, biscyclopentadienyltitaniumdiazide, trimethyl gallium, trimethyl indium, aluminum alkyls like trimethylaluminum, triethylaluminum, trimethylamine alane, dimethyl zinc, tetramethyl tin, trimethyl antimony, diethyl cadmium, tungsten carbony, or any combination thereof.

In some embodiments, the vaporizable precursor comprises, consists of, or consists essentially of at least one of elemental boron, phosphorus, decaborane, gallium halides, indium halides, antimony halides, arsenic halides, gallium halides, aluminum iodide, titanium iodide, MoO₂Cl₂, MoOCl₄, MoCl₅, WCl₅, WOCl₄, WCl₆, cyclopentadienylcycloheptatrienyltitanium (CpTiCht), cyclooctatetraenecyclopenta-dienyltitanium, biscyclopentadienyltitanium-diazide, In(CH₃)₂(hfac), dibromomethyl stibine, tungsten carbonyl, metalorganic β-diketonate complexes, metalorganic alkoxide complexes, metalorganic carboxylate complexes, metalorganic aryl complexes, metalorganic amido complexes, or any combination thereof. In some embodiments, the vaporizable precursor comprises, consists of, or consists essentially of at least one of MoO₂Cl₂, MoOCl₄, WO₂Cl₂, WOCl₄, or any combination thereof.

In some embodiments, the vaporizable precursor comprises, consists of, or consists essentially of at least one of any type of source material that can be liquefied either by heating or solubilization in a solvent including, for example and without limitation, at least one of decaborane, (B₁₀H₁₄), pentaborane (B₅H₉), octadecaborane (B₁₈H₂₂), boric acid (H₃BO₃), SbCl₃, SbCl₅, or any combination thereof. In some embodiments, the vaporizable precursor comprises, consists of, or consists essentially of at least one of at least one of AsCl₃, AsBr₃, AsF₃, AsF₅, AsH₃, As₄O₆, As₂Se₃m As₂S₂, As₂S₃, As₂S₅, As₂Te₃, B₄H₁₁, B₄H₁₀, B₃H₆N₃, BBr₃, BC₁₃, BF₃, BF₃·O(C₂H₅)₂, BF₃.HOCH₃, B₂H₆, F₂, HF, GeBr₄, GeCl₄, GeF₄, GeH₄, H₂, HCl, H₂Se, H₂Te, H₂S, WF₆, SiH₄, SiH₂Cl₂, SiHCI₃, SiCl₄, SiH₃Cl, NH₃, NH₃, Ar, Br₂, HBr, BrF₅, C₀₂, CO, COC₁₂, COF₂, C₁₂, CIF₃, CF₄, C₂F₆, C₃F₈, C₄F₈, C₅F₈, CHF₃, CH₂F₂, CH₃F, CH₄, SiH₆, He, HCN, Kr, Ne, Ni(CO)₄, HNO₃, NO, N₂, NO₂, NF₃, N₂O, C₈H₂₄O₄Si₄, PH₃, POCl₃, PCI₅, PF₃, PFS, SbH₃, SO₂, SF₆, SF₄, Si(OC₂H₅)₄, C₄H₁₆Si₄O₄, Si(CH₃)₄, SiH(CH₃)₃, TiCl₄, Xe, SiF₄, WOF₄, TaBr₅, TaCI₅, TaF₅, Sb(C₂H₅)₃, Sb(CH₃)₃, In(CH₃)₃, PBr₅, PBr₃, RuF₅, or any combination thereof.

In some embodiments, the module 114 can modify the surface by forming a coating on the surface. For example, the module 114 can modify the surface by coating the interior surfaces of the wetted flow path. In some embodiments, the module 114 are an atomic layer deposition coating module.

In some embodiments, the module 114 can be used to provide other surface treatments options besides providing a coating. For example, the module 114 can be used to provide passivation of the delivery system 102 as well as the manufacturing system 100. The materials of the surface can react with the vapor to form a layer which is chemically resistant. Some examples of useful reactions are those that form or improve a passive oxide layer such as trioxygen (O₃), peroxides, or permanganates. Other reactions might form stable carbide or nitrides on the surface such as those from nitrogen (N₂), methane, ammonia, etc. Additional reactions might form stable halides on the surface, such as those from fluorine (F₂), NF₃ plasma or XeF₂. Other useful reactions can leave the surface terminated with inert chemical species as is well-known from hexamethyldisilane.

In some embodiments, modifying the surface includes applying chemical sources from the module 114 to surfaces within manufacturing system 100, such as the delivery system 102 (e.g., the chemical supply cabinet 110).

In some embodiments, modifying the surface can include exposure to a single chemical species that passivates or chemisorbs to the surface. Modifying the surface can include cyclic exposure of at least two different species (e.g., fluorine (F₂), and nitrogen (N₂)).

In some embodiments, modifying the surface includes surface modification without the addition of materials to the surface. For example, modifying the surface can include modifying the surface without the addition of a specific coating.

In some embodiments, the more than one module 114 can be used. In some embodiments, the more than one module 114 can be the same as one another. In some embodiments, the more than one module 114 can be different than one another. For example, the first module 114 can be a coating module (e.g., an atomic layer deposition coating module) and the second module 114 can be a module for vapor deposition (e.g., a chemical vapor deposition module).

In some embodiments, the module 114 can be connected to the chemical supply cabinet 110 from an exterior of the chemical supply cabinet 110. Alternatively, the module 114 can be connected to the chemical supply cabinet 110 from an interior of the chemical supply cabinet 110.

The control unit 116 includes a microprocessor with non-volatile program memory and read/write memory for variable storage. In some embodiments, the control unit 116 is configured to automatically direct the module 114 to modify the surface (e.g., a surface of the manufacturing system 100). In some embodiments, the control unit 116 is connected to the module 114 via Wi-Fi, Bluetooth, network, cloud etc. For example, the control unit 116 can be physically separated from the module 114 and connected via Wi-Fi, Bluetooth, network, cloud etc. In some embodiments, the control unit 116 controls the module 114 by controlling the module 114 via the control unit 116 to automatically modify the surface. The control unit 116 can also be used to manually control the module 114.

In some embodiments, the control unit 116 is used to control the process of passivation when the module 114 is used to alter a composition of the surface. For example, the control unit 116 can be used to automate the passivation process. In some embodiments, the passivation process includes the following steps. A first step can be to isolate the ampoules 112 (e.g., a chemical ampoule) that is in the chemical supply cabinet 110 (e.g., via a valve function). A second step can include purging the supply line 120. In some embodiments, purging can require establishing a connection to a pump (which is downstream of the tool 130). In some embodiments, it may not be desired to modify (e.g., coat) an interior surface of the tool 130. In some embodiments, this can be achieved by establishing a bypass connection (through various valve switching functions) so that the materials (e.g., chemicals) needed for the modification/coating do not get pumped through the tool 130.

A third step can include opening the module 114 to execute the modification/coating/passivation sequence. In some embodiments, more than one module 114 is used during the execution the modification/coating/passivation sequence. In some embodiments, the sequence can include at least two options. These options include the use of processing lines connected to the module 114. The processing lines connecting the module 114 and the supply line 120 can include gas lines, manifolds, valves, orifices, pressure transducers, and other supply line mechanicals.

Option 1 can include the following steps: (i) establish a carrier gas flow (e.g., inert gas referred to as a “chemical A” such as nitrogen or argon); (ii) [pulse the carrier gas (e.g., “chemical A”) for “x” seconds—wait—pulse “chemical B” for “y” seconds—wait] for “n” number of times; in some embodiments, all this has to go through a bypass line before it enters the tool 130. In some embodiments, the “wait” is on the order of 5 seconds to 60 seconds. In some embodiments, “n” is between 1 and 10,000. In some embodiment, x” and “y” seconds can vary from less than one second to more than 120 seconds.

In some embodiments, Option 1 can provide a thickness ranging from 1 nanometer to 1 micron. In some embodiments, the thickness ranges from 20 nanometers to 120 nanometers.

For Option 1, “chemical A” and “chemical B” are different from one another. Chemical A and chemical B can be any compound or chemical element described herein.

In some embodiments, after pulsing the carrier gas (e.g., “chemical A”) for “x” seconds and after the “wait,” the method can include purging or evacuating the carrier gas. Purging can include flowing a new gas to push out “chemical A.” Evacuating can include pulling a vacuum to draw out the “chemical A.” Similarly, the method can include purging or evacuating “chemical B” after pulsing “chemical B” for “y” seconds.

Option 2 can include the following steps: (i) close off a pump valve; (ii) pulse “chemical A” for “x” seconds—wait (for an extended period of time—e.g., several minutes to hours); (iii) open pump valve then evacuate or purge “chemical A;” (iv) repeat steps (i) through (iii) “n” times. In some embodiments, the “wait” is on the order of 5 seconds to 60 seconds. In some embodiments, “n” can range from 1 to 10,000. In some embodiment, x” seconds can vary from less than one second to more than 120 seconds. “Chemical A” can be any compound or chemical element described herein.

In some embodiments, Option 2 can provide a single monolayer or multiple monolayers. In some embodiments, a single monolayer can have a thickness of up to 50 nanometers. In some embodiments, the multiple monolayers can have a cumulative thickness of several microns.

In some embodiments, a coating of the present disclosure, such as a protective coating, that can include one or more of coating materials selected from the group consisting of Al₂O₃, oxides of the formula MO, wherein M is Ca, Mg, or Be; oxides of the formula M′O₂, wherein M′ is a stoichiometrically acceptable metal; and oxides of the formula Ln₂O₃, wherein Ln is a lanthanide element, e.g., La, Sc, or Y. More generally, the coating may comprise a metal oxide for which the free energy of reaction with the material that is contacted with a surface (e.g., a metal surface) in the operation of the system, is greater than or equal to zero.

The metal oxide, nitride, or halide in various embodiments may comprise at least one oxide, nitride, or halide of one or more of Cr, Fe, Co, and Ni, and may comprise in other embodiments at least one oxide, nitride, or halide of one or more of Cr, Fe, and Ni, or any other suitable metal oxide, nitride, or halide species. The gas that is reactive with the metal oxide, nitride, or halide to form a reaction product that is deleterious to the structure, material, or system and its use or operation, may comprise Al₂Cl₆, WCl₅, MoCl₅, WCl₆, MoO₂Cl₂, MoOCl₄, or WOCl₄.

The coating (such as a protective coating that is applied to the surface) in the aforementioned method may comprise one or more of coating materials selected from the group consisting of Al₂O₃, oxides of the formula MO, wherein M is Ca, Mg, or Be; oxides of the formula M′O₂, wherein M′ is a stoichiometrically acceptable metal; and oxides of the formula Ln₂O₃, wherein Ln is a lanthanide element, e.g., La, Sc, or Y. More generally, the protective coating may comprise a metal oxide for which the free energy of reaction with the gas that is contacted with a surface (e.g., the metal surface) in the use or operation of the structure, material, or system, is greater than or equal to zero.

A fourth step can include closing the at least one module 114 (e.g., module 114 can be reactant source for the delivery system 102) and purge the supply line 120—either by just pumping (through the bypass line), or by pump and purge cycles using an inert gas that is being introduced from the chemical supply cabinet 110 (e.g., see inert gas line 270 of FIG. 2 and inert gas line 370 of FIG. 3).

A fifth step can include conducting a leak back sequence of the supply line 120.

A sixth step can include opening the ampoules 112 (e.g., a chemical ampule) that is in the chemical supply cabinet 110 (e.g., via a valve function)—and optionally pulsing (either into the tool 130 or still through the bypass connection) to re-establish proper chemical gas line conditions of the supply line 120.

The supply line 120 can include gas lines, manifolds, valves, orifices, pressure transducers, and other supply line mechanicals.

In some embodiments, the tool 130 can be a processing tool, such as a semiconductor processing tool. In some embodiments, the surface can be a surface of the tool 130 (e.g., a surface of the semiconductor processing tool).

The vacuum pump line 140 can include gas lines, manifolds, valves, orifices, pressure transducers, and other supply line mechanicals.

FIG. 2 displays a delivery system 202. For simplicity of this Specification, features of the delivery system 202 that have been previously described respective of FIG. 1 will not be redescribed in additional detail unless specifically indicated otherwise. The delivery system 202 includes a chemical supply cabinet 210 and a supply line 220. The chemical supply cabinet 210 can include a first ampoule 212A, a second ampoule 212B (the first ampoule 212A and the second ampoule 212B collectively referred to as the ampoules 212), a module 214, a control unit 216, processing lines 260, and an inert gas line 270. In some embodiments, the chemical supply cabinet 110 does not include the control unit 116.

In some embodiments, only one ampoule is connected to supply line 220. For example, after the first ampoule 212A is emptied, the first ampoule 212A can be disconnected from the supply line 220. The second ampoule 212B can then be connected to the supply line 220. The processing lines 260 can include gas lines, manifolds, valves, orifices, pressure transducers, and other supply line mechanicals.

FIG. 3 displays a delivery system 302. For simplicity of this Specification, features of the delivery system 302 that have been previously described respective of FIGS. 1 and 2 will not be redescribed in additional detail unless specifically indicated otherwise. The delivery system 302 includes a chemical supply cabinet 310 and a supply line 320. The chemical supply cabinet 310 can include an ampoule 312, a module 314, a control unit 316, processing lines 360, and an inert gas line 370. In some embodiments, the delivery system 302 does not include control unit 316. During use of the delivery system 302, the ampoule 312 can be disconnected from the processing lines 360 and the module 314 can be connected to the processing lines 360. Alternatively, the ampoule 312 can be connected to the processing lines 360, and the module 314 can be disconnected to the processing lines 360.

FIG. 4 displays a module 414. For simplicity of this Specification, features of the module 414 that have been previously described respective of FIGS. 1-3 will not be redescribed in additional detail unless specifically indicated otherwise. In some embodiments, the module 414 can be a atomic layer deposition coating module. The module 414 can include a precursor source 406 and a co-reactant source 408. In some embodiments, the precursor source 406 and/or the co-reactant source 408 can be an ampoule. The module 414 can include an inert gas line 470A connected to the precursor source 406. The module 414 can include an inert gas line 470B connected to the co-reactant source 408. The module 414 can include processing lines 460 can be configured to be inserted into a chemical supply cabinet (e.g., supply cabinet 110, supply cabinet 210, or supply cabinet 310) to connect to another device, such as a supply line (e.g., supply line 120, supply line 220, or supply line 320).

In some embodiments, the module 414 can be connected to a chemical supply cabinet on the outside, instead of being inserted into the chemical supply cabinet.

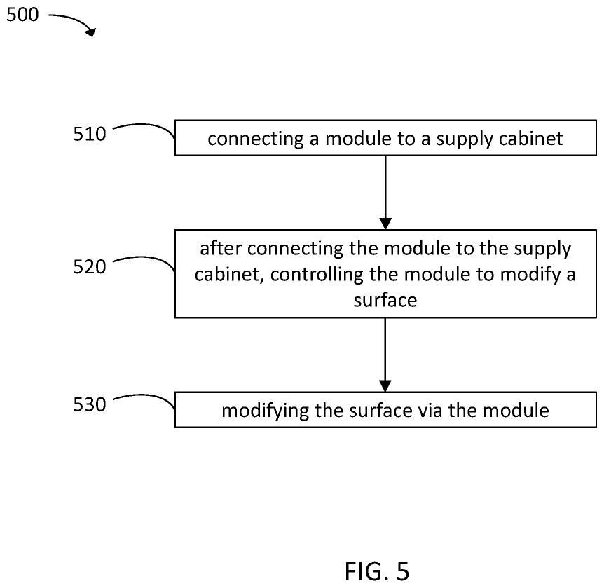

FIG. 5 shows an exemplary flowchart according to some of the embodiments of the method 500 for modifying a surface. The method includes connecting 510 a module to a chemical supply cabinet. The method further includes after connecting the module to the chemical supply cabinet, controlling 520 the module to modify a surface. The method further includes modifying 530 the surface via the modifying the surface via the module.

In some embodiments, the module is an atomic layer deposition coating module. Modifying the surface can include forming a coating on the surface. Forming the coating on the surface can include using atomic layer deposition.

In some embodiments, the module is a chemical vapor deposition module. Modifying the surface includes altering a composition of the surface, e.g., via vapors from the chemical vapor deposition module.

In some embodiments, the method 500 includes connecting an ampoule to the chemical supply cabinet, connecting a supply line to the chemical supply cabinet, connecting a tool to the supply line, or combinations thereof. In some embodiments, connecting the module to the chemical supply cabinet comprises connecting the module to the chemical supply cabinet, while the module remains on an exterior of the chemical supply cabinet. In some embodiments, the method 500 includes controlling the module, e.g., controlling the module via a control unit to automatically modify the surface. module.

Aspects

Various Aspects are described below. It is to be understood that any one or more of the features recited in the following Aspect(s) can be combined with any one or more other Aspect(s).

Aspect 1. A system comprising: a chemical supply cabinet; a module configured to modify a surface; and a control unit connected to the module, wherein the control unit is configured to direct the modifying of the surface.

Aspect 2. The system of Aspect 1, wherein the system is configured to connect to a semiconductor processing tool.

Aspect 3. The system of Aspect 1 or Aspect 2, wherein the surface comprises an interior surface of the semiconductor processing tool.

Aspect 4. The system as in any of the preceding Aspects, wherein the module is configured to modify the surface by altering a composition of the surface.

Aspect 5. The system as in any of the preceding Aspects, wherein the module is configured to modify the surface by forming a coating on the surface.

Aspect 6. The system as in any of the preceding Aspects, wherein the module is an atomic layer deposition coating module.

Aspect 7. The system as in any of the preceding Aspects, wherein the module is configured to be connected to the chemical supply cabinet from an exterior of the chemical supply cabinet.

Aspect 8. The system as in any of the preceding Aspects, wherein the control unit is configured to automatically direct the module to modify the surface of the system.

Aspect 9. A method comprising: connecting a module to a chemical supply cabinet; after connecting the module to the chemical supply cabinet, controlling the module to modify a surface; and modifying the surface via the module.

Aspect 10. The method of Aspect 9, wherein the module is an atomic layer deposition coating module.

Aspect 11. The method of Aspect 9 or Aspect 10, wherein the modifying the surface comprises forming a coating on the surface.

Aspect 12. The method of Aspect 11, wherein the forming the coating on the surface comprises using atomic layer deposition.

Aspect 13. The method as in any of the preceding Aspects, further comprising connecting an ampoule to the chemical supply cabinet, connecting a supply line to the chemical supply cabinet, connecting a tool to the supply line, or combinations thereof.

Aspect 14. The method as in any of the preceding Aspects, wherein the connecting the module to the chemical supply cabinet comprises connecting the module to the chemical supply cabinet, while the module remains on an exterior of the chemical supply cabinet.

Aspect 15. The method as in any of the preceding Aspects, wherein the controlling the module comprises controlling the module via a control unit to automatically modify the surface.

Aspect 16. A system comprising: a chemical supply cabinet, wherein a structure of the chemical supply cabinet defines an interior volume of the chemical supply cabinet; a module connected to the interior volume of the chemical supply cabinet; a tool connected to the module; and a supply line connecting the chemical supply cabinet to the tool, wherein, after connecting the module to the chemical supply cabinet, the module is configured to modify a surface.

Aspect 17. The system of Aspect 16, wherein a control unit is connected to the module, and wherein the control unit is configured to direct the module.

Aspect 18. The system of Aspect 16 or Aspect 17, wherein the module is an atomic layer deposition coating module.

Aspect 19. The system as in any of the preceding Aspects, wherein the tool is a semiconductor processing tool.

Aspect 20. The system as in any of the preceding Aspects, wherein the surface comprises an interior surface within the chemical supply cabinet, an interior surface of the supply line, a wettable-surface of the tool, or combinations thereof.

The terminology used herein is intended to describe embodiments and is not intended to be limiting. The terms “a,” “an,” and “the” include the plural forms as well, unless clearly indicated otherwise. The terms “comprises” and/or “comprising,” when used in this Specification, specify the presence of the stated features, integers, steps, operations, elements, and/or components, but do not preclude the presence or addition of one or more other features, integers, steps, operations, elements, and/or components.

It is to be understood that any of the embodiments or any portion(s) thereof may be combined with any of the other embodiments without departing from the scope of the present disclosure. It is also to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A system comprising:
a chemical supply cabinet;
a module configured to modify a surface; and
a control unit connected to the module, wherein the control unit is configured to direct the modifying of the surface.

2. The system of claim 1, wherein the system is configured to connect to a semiconductor processing tool.

3. The system of claim 2, wherein the surface comprises an interior surface of the semiconductor processing tool.

4. The system of claim 1, wherein the module is configured to modify the surface by altering a composition of the surface.

5. The system of claim 1, wherein the module is configured to modify the surface by forming a coating on the surface.

6. The system of claim 1, wherein the module is an atomic layer deposition coating module.

7. The system of claim 1, wherein the module is configured to be connected to the chemical supply cabinet from an exterior of the chemical supply cabinet.

8. The system of claim 1, wherein the control unit is configured to automatically direct the module to modify the surface of the system.

9. A method comprising:
connecting a module to a chemical supply cabinet;
after connecting the module to the chemical supply cabinet, controlling the module to modify a surface; and
modifying the surface via the module.

10. The method of claim 9, wherein the module is an atomic layer deposition coating module.

11. The method of claim 9, wherein the modifying the surface comprises forming a coating on the surface.

12. The method of claim 11, wherein the forming the coating on the surface comprises using atomic layer deposition.

13. The method of claim 9, further comprising connecting an ampoule to the chemical supply cabinet, connecting a supply line to the chemical supply cabinet, connecting a tool to the supply line, or combinations thereof.

14. The method of claim 9, wherein the connecting the module to the chemical supply cabinet comprises connecting the module to the chemical supply cabinet, while the module remains on an exterior of the chemical supply cabinet.

15. The method of claim 9, wherein the controlling the module comprises controlling the module via a control unit to automatically modify the surface.

16. A system comprising:
a chemical supply cabinet, wherein a structure of the chemical supply cabinet defines an interior volume of the chemical supply cabinet;
a module connected to the interior volume of the chemical supply cabinet;
a tool connected to the module; and
a supply line connecting the chemical supply cabinet to the tool,
wherein, after connecting the module to the chemical supply cabinet, the module is configured to modify a surface.

17. The system of claim 16, wherein a control unit is connected to the module, and wherein the control unit is configured to direct the module.

18. The system of claim 16, wherein the module is an atomic layer deposition coating module.

19. The system of claim 16, wherein the tool is a semiconductor processing tool.

20. The system of claim 16, wherein the surface comprises an interior surface of the chemical supply cabinet, an interior surface of the supply line, a wettable-surface of the tool, or combinations thereof.
